(19) United States
(12) Patent Application Publication
(10) Pub. No.: US 2008/0219343 A1
(43) Pub. Date: Sep. 11, 2008

(54) SYSTEMS AND METHODS FOR PROCESSING A SIGNAL WITHIN A COMMUNICATIONS SYSTEM WITH A SUPERIMPOSED REFERENCE SIGNAL

(75) Inventors: Huaming Wu, Vancouver, WA (US); John M. Kowalski, Camas, WA (US)

Correspondence Address: MADSON & AUSTIN, 15 WEST SOUTH TEMPLE, SUITE 900, SALT LAKE CITY, UT, 84101, US

(73) Assignee: Sharp Laboratories of America, Inc., Camas, WA (US)

(21) Appl. No.: 11/684,519

(22) Filed: Mar. 9, 2007

(51) Int. Cl. H03H 7/30

(52) U.S. Cl. 375/232; 370/203

(57) ABSTRACT

A method for processing a signal within a communications system is described. A signal transmitted over a channel is received that includes an information signal and a reference signal. The information signal includes data. The reference signal is superimposed on the data. A channel impulse response of the channel is estimated based on the reference signal. The information signal is equalized based on the estimation of the channel impulse response by compensating the signal, estimating the information signal, canceling the reference signal and recovering the data.

### TECHNICAL FIELD

The present invention relates generally to computers and computer-related technology. More specifically, the present invention relates to systems and methods for processing a signal within a communications system with a superimposed reference signal.

### BACKGROUND

A wireless communication system typically includes a base station in wireless communication with a plurality of user devices (which may also be referred to as mobile stations, subscriber units, access terminals, etc.). The base station transmits data to the user devices over a radio frequency (RF) communication channel. The term “downlink” refers to transmission from a base station to a user device, while the term “uplink” refers to transmission from a user device to a base station.

Orthogonal frequency division multiplexing (OFDM) is a modulation and multiple-access technique whereby the transmission band of a communication channel is divided into a number of equally spaced sub-bands. A sub-carrier carrying a portion of the user information is transmitted in each sub-band, and every sub-carrier is orthogonal with every other sub-carrier. Sub-carriers are sometimes referred to as “tones.” OFDM enables the creation of a very flexible system architecture that can be used efficiently for a wide range of services, including voice and data. OFDM is sometimes referred to as discrete multi-tone transmission (DMT).

The 3^{rd} Generation Partnership Project (3GPP) is a collaboration of standards organizations throughout the world. The goal of 3GPP is to make a globally applicable third generation (3G) mobile phone system specification within the scope of the IMT-2000 (International Mobile Telecommunications-2000) standard as defined by the International Telecommunication Union. The 3GPP Long Term Evolution (“LTE”) Committee is considering OFDM as well as OFDM/OQAM (Orthogonal Frequency Division Multiplexing/Offset Quadrature Amplitude Modulation), as a method for downlink transmission, as well as OFDM transmission on the uplink.

Wireless communications systems (e.g., Time Division Multiple Access (TDMA), Orthogonal Frequency-Division Multiplexing (OFDM)) usually calculate an estimation of a channel impulse response between the antennas of a user device and the antennas of a base station for coherent receiving. Channel estimation may involve transmitting known reference signals that are multiplexed with the data. However, wireless communication systems may be able to send the known reference signals contemporaneously with the data. The reference signal may be superimposed with the data. As such, benefits may be realized by providing systems and methods to process a signal within a communications system. In particular, benefits may be realized by providing systems and methods to estimate the channel and compensate the channel for channel-induced defects in order to improve the accuracy of data recovery for wireless communication systems utilizing superimposed reference signal(s).

### BRIEF DESCRIPTION OF THE DRAWINGS

Exemplary embodiments of the invention will become more fully apparent from the following description and appended claims, taken in conjunction with the accompanying drawings. Understanding that these drawings depict only exemplary embodiments and are, therefore, not to be considered limiting of the invention's scope, the exemplary embodiments of the invention will be described with additional specificity and detail through use of the accompanying drawings in which:

FIG. 1 illustrates an exemplary wireless communication system in which embodiments may be practiced;

FIG. 2 illustrates some characteristics of a transmission band of an RF communication channel in accordance with an OFDM-based system;

FIG. 3 illustrates communication channels that may exist between an OFDM transmitter and an OFDM receiver according to an embodiment;

FIG. 4 illustrates a block diagram of certain components in an embodiment of a receiver;

FIG. 5 is a flow diagram illustrating one embodiment of a method for processing a signal;

FIG. 6 is a flow diagram illustrating one embodiment of a method for equalizing an information signal;

FIG. 7 is a block diagram illustrating a further embodiment of the receiver;

FIG. 8 illustrates a block diagram of one embodiment of a transmitter which may transmit data signals contemporaneously with a reference signal to a receiver;

FIG. 9 is a chart illustrating one embodiment of results regarding the mean square error (MSE) of channel estimation for a single antenna system;

FIG. 10 is a chart illustrating one embodiment of results regarding the mean square error (MSE) of channel estimation for a multiple antenna system;

FIG. 11 is a chart illustrating one embodiment of the results regarding the Bit Error Ratio (BER) performance of a single antenna system;

FIG. 12 is a example of the results regarding the BER performance of a multiple antenna system; and

FIG. 13 illustrates various components that may be utilized in a communications device.

### DETAILED DESCRIPTION

A method for processing a signal within a communications system is described. A signal transmitted over a channel is received that includes an information signal and a reference signal. The information signal includes data. The reference signal is superimposed on the data. A channel impulse response of the channel is estimated based on the reference signal. The information signal is equalized based on the estimation of the channel impulse response by compensating the signal, estimating the information signal, canceling the reference signal and recovering the data.

In one embodiment, the signal is received by a communications device comprising a single antenna. In a further embodiment, one or more signals is received by a communications device comprising multiple antennas.

A vector of the signal may be multiplied by a conjugate transposed vector of a symbol of the reference signal for a single antenna communications device. A matrix of the signal may be multiplied by a conjugate transposed matrix of symbols of one or more reference signals for a multiple antenna communications device.

In one embodiment, equalizing the information signal for a single antenna communications device further comprises: multiplying a vector of the information signal by the inverse of a channel estimation and estimating the information signal; canceling the reference signal; and multiplying the information signal by the pseudo-inverse of a linear transformation matrix used at a transmitter to recover the data.

In a further embodiment, equalizing the information signal for a multiple antenna communications device further comprises: multiplying a matrix of the information signal by the inverse of a channel estimation matrix and estimating the information signal; canceling the reference signal; and multiplying the information signal by the pseudo-inverse of a linear transformation matrix used at a transmitter to recover the data.

A class of linear receivers may be utilized. In one embodiment, the channel impulse response is estimated using zero-forcing estimation. The channel impulse response may also be estimated using minimum mean square error (MMSE) estimation.

The information signal may be estimated using zero-forcing estimation. The estimated may be estimated using minimum mean square error (MMSE) estimation.

A communications device that is configured to process a signal within a communications system is also described. The device includes a processor and memory in electronic communication with the processor. Instructions are stored in the memory. A signal transmitted over a channel that includes an information signal and a reference signal is received, wherein the information signal comprises data, and wherein the reference signal is superimposed on the data. A channel impulse response of the channel is estimated based on the reference signal. The information signal is equalized based on the estimation of the channel impulse response by compensating the signal, estimating the information signal, canceling the reference signal and recovering the data.

A computer-readable medium comprising executable instructions is also described. A signal transmitted over a channel that includes an information signal and a reference signal is received, wherein the information signal comprises data, and wherein the reference signal is superimposed on the data. A channel impulse response of the channel is estimated based on the reference signal. The information signal is equalized based on the estimation of the channel impulse response by compensating the signal, estimating the information signal, canceling the reference signal and recovering the data.

Various embodiments of the invention are now described with reference to the Figures, where like reference numbers indicate identical or functionally similar elements. The embodiments of the present invention, as generally described and illustrated in the Figures herein, could be arranged and designed in a wide variety of different configurations. Thus, the following more detailed description of several exemplary embodiments of the present invention, as represented in the Figures, is not intended to limit the scope of the invention, as claimed, but is merely representative of the embodiments of the invention.

The word “exemplary” is used exclusively herein to mean “serving as an example, instance, or illustration.” Any embodiment described herein as “exemplary” is not necessarily to be construed as preferred or advantageous over other embodiments.

Many features of the embodiments disclosed herein may be implemented as computer software, electronic hardware, or combinations of both. To clearly illustrate this interchangeability of hardware and software, various components will be described generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention.

Where the described functionality is implemented as computer software, such software may include any type of computer instruction or computer executable code located within a memory device and/or transmitted as electronic signals over a system bus or network. Software that implements the functionality associated with components described herein may comprise a single instruction, or many instructions, and may be distributed over several different code segments, among different programs, and across several memory devices.

As used herein, the terms “an embodiment”, “embodiment”, “embodiments”, “the embodiment”, “the embodiments”, “one or more embodiments”, “some embodiments”, “certain embodiments”, “one embodiment”, “another embodiment” and the like mean “one or more (but not necessarily all) embodiments of the disclosed invention(s)”, unless expressly specified otherwise.

The term “determining” (and grammatical variants thereof) is used in an extremely broad sense. The term “determining” encompasses a wide variety of actions and therefore “determining” can include calculating, computing, processing, deriving, investigating, looking up (e.g., looking up in a table, a database or another data structure), ascertaining and the like. Also, “determining” can include receiving (e.g., receiving information), accessing (e.g., accessing data in a memory) and the like. Also, “determining” can include resolving, selecting, choosing, establishing and the like.

The phrase “based on” does not mean “based only on,” unless expressly specified otherwise. In other words, the phrase “based on” describes both “based only on” and “based at least on.”

Multiple-antenna wireless communication links may have high data rates with low error probabilities, particularly if a wireless channel response is known at a receiver. In order to learn the channel response of the channel, the receiver may require the transmitter to send known training signals during some portion of the transmission interval. However, given a multi-antenna wireless link with multiple transmit and receive antennas, a decision may be made regarding the amount of energy that should be used for transmitting the training signals.

One approach is to utilize a block-fading channel, where the channel is constant for some discrete time interval T, after which it changes to an independent value for the next interval of duration-T, etc. The training of a time division multiplex (TDM) system may include the training signal and data being allocated on different time slots. For example, data may be sent for T_{d} discrete time instants as x^{(d)}(t). In addition, the training signal (also known as a pilot signal or a reference signal) may be sent for Tₚ time instants as x^{(p)}(t). As such, the block interval may be represented as T=T_{d}+Tₚ. Further, x^{(d)}(t) and x^{(p)}(t) may be allowed to be sent at different powers or energies per unit time.

The optimal training energy (Eₒₚₜ) to maximize the channel capacity, as a fraction of total energy, based on assumptions of Additive White Gaussian Noise (AWGN), may be seen to be:

$${ρ}_{p} {T}_{p} / ρ T = \{ \begin{matrix}1 - γ + \sqrt{γ ( γ - 1 )} for {T}_{d} > {m}_{T} \\ 1 / 2 for {T}_{d} = {m}_{T} \\ 1 - γ - \sqrt{γ ( γ - 1 )} for {T}_{d} < {m}_{T}\end{matrix} , \qquad Equation ( 1 )$$

where

$$γ = \frac{{m}_{T} + ρ T}{ρ T ( 1 - \frac{{m}_{T}}{{T}_{d}} )} ,$$

m_{T} is the number of transmit antenna(s) and ρ is the overall signal-to-noise ratio (SNR). The total energy is given by ρT, and the energy due to the data and the pilot signal respectively is given by ρ_{d}T_{d} and ρₚTₚ.

If the transmit powers of the pilot signal and the data are allowed to vary, the optimal training period should be as short as possible (with Tₚ=m_{T}). This implies a large (Eₒₚₜ) when T is large, thus T_{d}>m_{T}. However, a transmitted peak-to-average power ratio (PAPR) constraint may prevent the implementation of high power in a short training period interval.

In order to avoid the restraint imposed by the PAPR, a pilot signal may be superimposed into the data. In other words, the pilot signal may be hidden in the data through implementation of a linear transformation. For example, instead of transmitting:

$${S}_{TDM} = [ \sqrt{\frac{{ρ}_{p}}{{m}_{T}}} {X}^{( p )} \sqrt{\frac{{ρ}_{d}}{{m}_{T}}} {X}^{( d )} ] \qquad Equation ( 2 )$$

where X^{(p)} (a m_{T}×m_{T} pilot matrix) and X^{(d)} (a (T−m_{T})×m_{T} data matrix) are on different time slots as in TDM pilot training. The transmitted signal is then given by:

$$S = [ \sqrt{\frac{{ρ}_{p}}{{m}_{T}}} {PX}^{( p )} + \sqrt{\frac{{ρ}_{d}}{{m}_{T}}} {QX}^{( d )} ] \qquad \text{Equation} ( 3 )$$

where the matrix P is a deterministic T×m_{T} matrix, which spreads out the energy of the pilot signal X^{(p)} into a T×m_{T} space; the matrix Q is also a deterministic T×(T−m_{T}) matrix, whose columns are orthogonal to the T×m_{T} matrix of pilot signal PX^{(p)}. Hereinafter, PX^{(p)} is referred to as pilot part and QX^{(d)} is referred to as data part. In one embodiment, for a given ρ, T and m_{T}, Tₚ is chosen to be m_{T} and T_{d}=T−Tₚ. Then ρ_{d} and ρₚ may be determined by equation (1) where ρT=ρ_{d} T_{d}+ρₚ Tₚ.

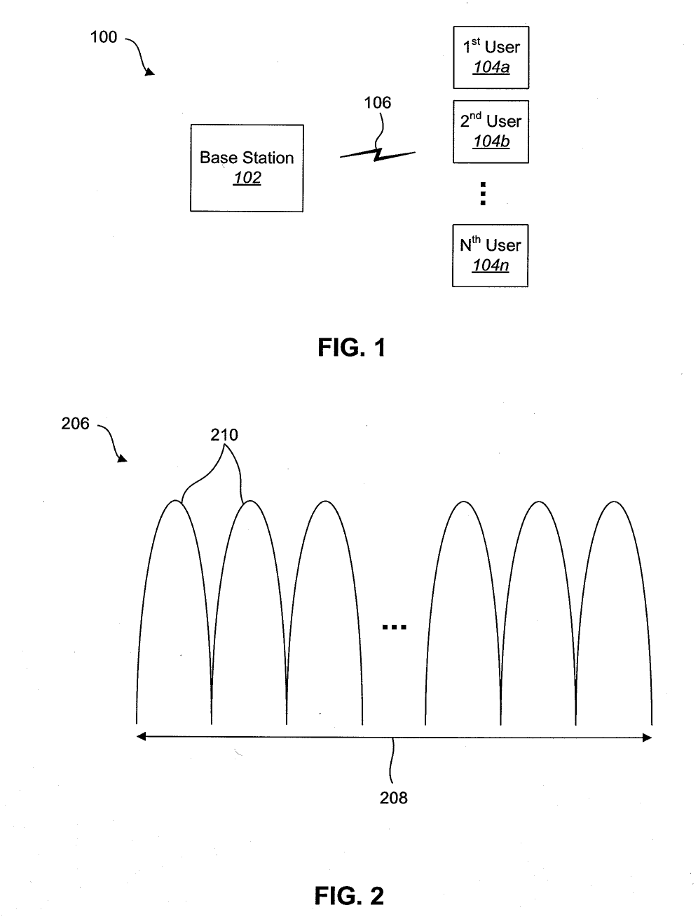

FIG. 1 illustrates an exemplary wireless communication system 100 in which embodiments may be practiced. A base station 102 is in wireless communication with a plurality of user devices 104 (which, as indicated above, may also be referred to as mobile stations, subscriber units, access terminals, etc.). A first user device 104a, a second user device 104b, and an Nth user device 104n are shown in FIG. 1. The base station 102 transmits data to the user devices 104 over a radio frequency (RF) communication channel 106.

As used herein, the term “OFDM transmitter” refers to any component or device that transmits OFDM signals. An OFDM transmitter may be implemented in a base station 102 that transmits OFDM signals to one or more user devices 104. Alternatively, an OFDM transmitter may be implemented in a user device 104 that transmits OFDM signals to one or more base stations 102.

The term “OFDM receiver” refers to any component or device that receives OFDM signals. An OFDM receiver may be implemented in a user device 104 that receives OFDM signals from one or more base stations 102. Alternatively, an OFDM receiver may be implemented in a base station 102 that receives OFDM signals from one or more user devices 104.

FIG. 2 illustrates some characteristics of a transmission band 208 of an RF communication channel 206 in accordance with an OFDM-based system. As shown, the transmission band 208 may be divided into a number of equally spaced sub-bands 210. As mentioned above, a sub-carrier carrying a portion of the user information is transmitted in each sub-band 210, and every sub-carrier is orthogonal with every other sub-carrier.

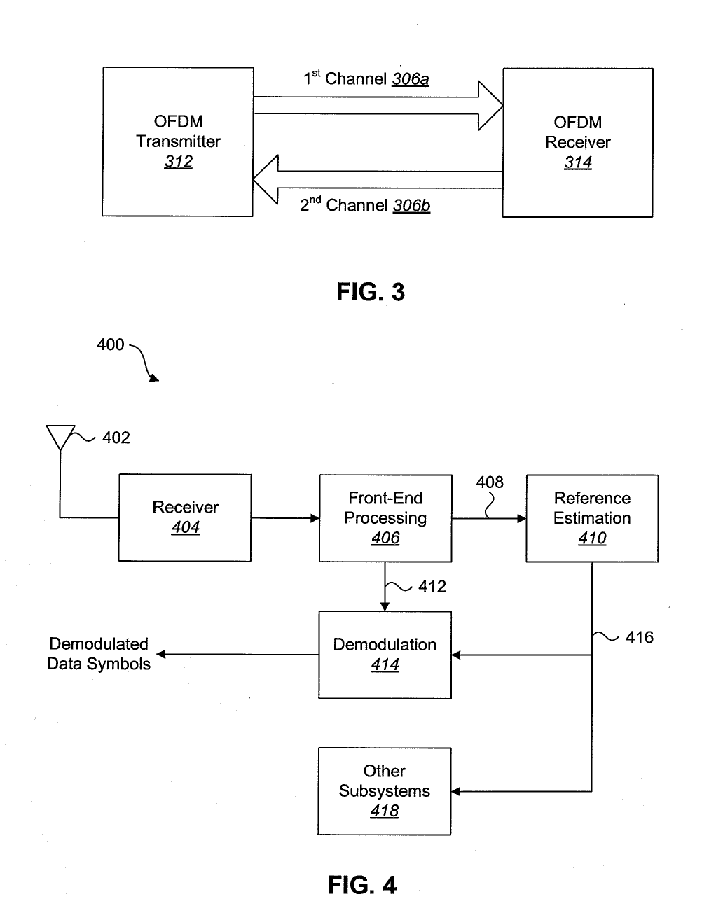

FIG. 3 illustrates communication channels 306 that may exist between an OFDM transmitter 312 and an OFDM receiver 314 according to an embodiment. As shown, communication from the OFDM transmitter 312 to the OFDM receiver 314 may occur over a first communication channel 306a. Communication from the OFDM receiver 314 to the OFDM transmitter 312 may occur over a second communication channel 306b.

The first communication channel 306a and the second communication channel 306b may be separate communication channels 306. For example, there may be no overlap between the transmission band of the first communication channel 306a and the transmission band of the second communication channel 306b.

FIG. 4 illustrates a block diagram 400 of certain components in an embodiment of a receiver 404. Other components that are typically included in the receiver 404 may not be illustrated for the purpose of focusing on the novel features of the embodiments herein.

A signal may be received at an antenna 402. In one embodiment, the signal includes both a reference signal and an information signal that includes data sent from a transmitter (not shown). The reference signal may be superimposed with the data. The received signal is provided by the antenna 402 to the receiver 404. The receiver 404 down-converts the received signal and provides it to a front-end processing component 406. The front-end processing component 406 may separate the reference signal from the data. The front-end processing component 406 may provide the reference signal 408 to a reference estimation component 410. The reference signal 408 typically includes noise and usually suffers from fading. The front-end processing component 406 may also provide the data 412 to a demodulation component 414 that demodulates the data.

The reference estimation component 410 may provide an estimated reference signal 416 to the demodulation component 414. The reference estimation component 410 may also provide the estimated reference signal 416 to other subsystems 418.

Additional processing takes place at the receiver 404. Generally, the reference estimation component 410 operates to estimate the reference signal and effectively clean-up the reference signal by reducing the noise and estimating the original reference (also referred to as a pilot) signal that was transmitted.

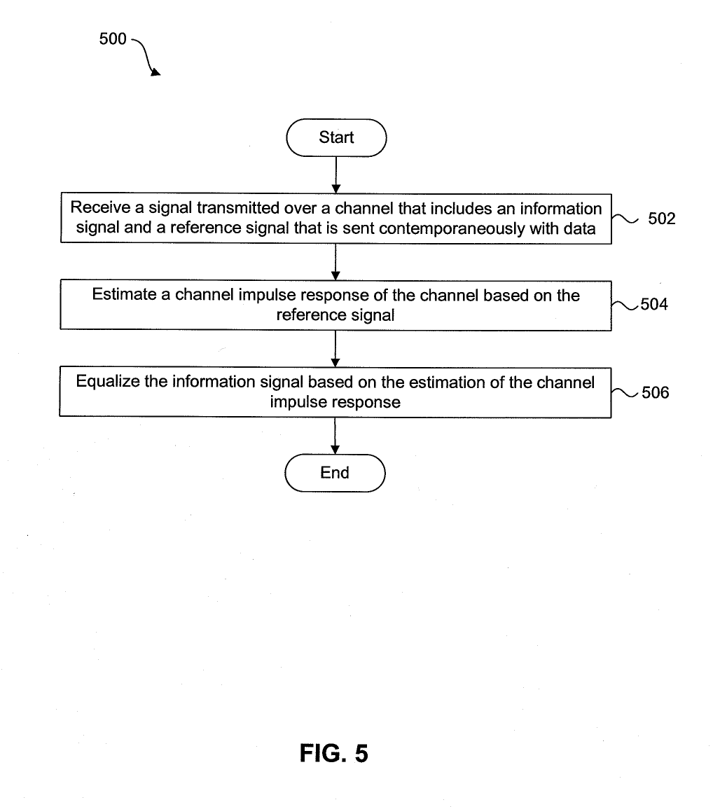

FIG. 5 is a flow diagram illustrating one embodiment of a method 500 for processing a signal. In one embodiment, the method 500 may be implemented by a receiver. A signal transmitted over a channel may be received 502. The received signal may include an information signal and a reference signal that is sent contemporaneously with data. In other words, the reference signal may be superimposed on the data. The information signal may include the data. As previously explained, the reference signal may be referred to as a pilot signal.

In one embodiment, a channel impulse response of the channel may be estimated 504. The estimation of the channel impulse response of the channel may be based on the reference signal. The information signal may be equalized 506. In one embodiment, the equalization of the information signal is based on the estimation of the channel impulse response of the channel. A description of equalizing the information signal is provided below.

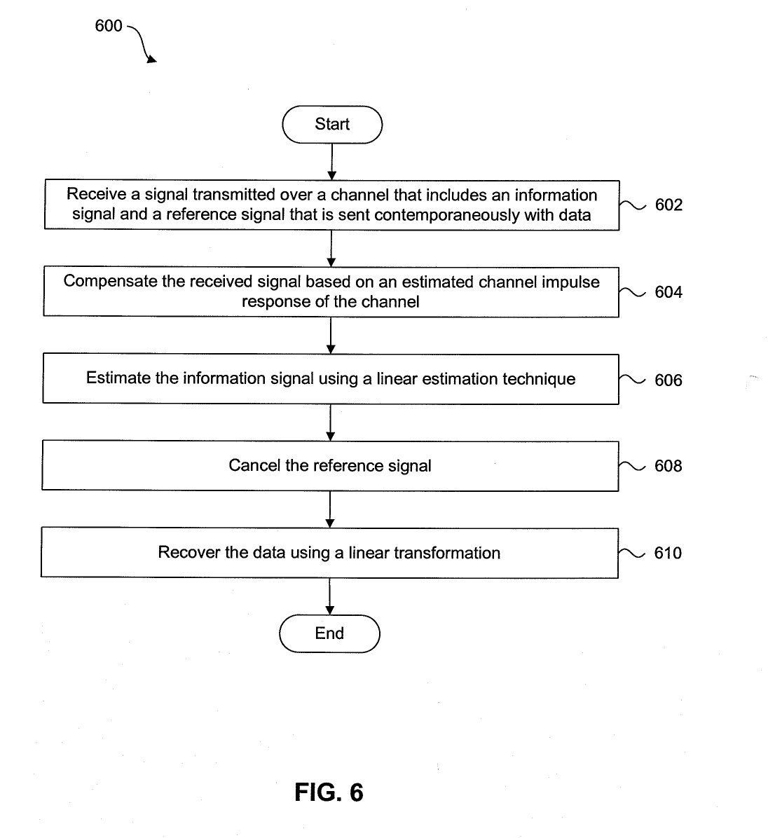

FIG. 6 is a flow diagram illustrating one embodiment of a method 600 for equalizing an information signal. A signal transmitted over a channel may be received 602. The received signal may include an information signal and a reference signal that is sent contemporaneously with data. The data may be included as a part of the information signal. In one embodiment, the received signal is compensated 604 based on an estimated channel impulse response of the channel. The received signal may be compensated for channel-induced defects in order to improve the accuracy in recovering the data from the received signal. The information signal may be estimated 606 using a linear estimation technique. In one embodiment, the reference signal is canceled 608. In other words, the reference signal is separated from the data. The data may be recovered 610 using a linear transform. In one embodiment, the recovered data is an estimate of the data originally transmitted as part of the information signal.

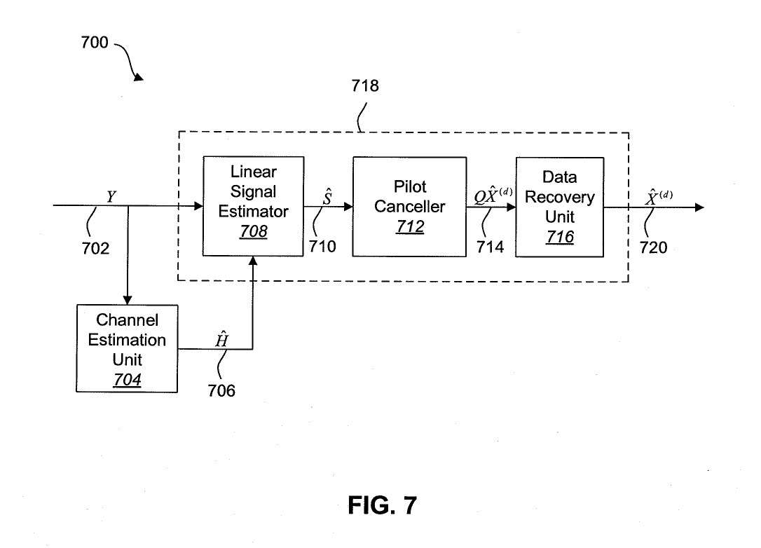

FIG. 7 is a block diagram illustrating a further embodiment of the receiver 700. The receiver 700 may receive a received signal Y 702. The received signal Y 702 may be transmitted from a transmitter (not shown). In addition, the received signal Y 702 may be transmitted over a channel (which may be represented as “H”) and may include a reference signal superimposed with data. The receiver 700 may include a channel estimation unit 704 that may estimate a channel impulse response Ĥ 706 of the channel used to transmit the received signal Y 702. The receiver 700 may also include a channel equalization unit 718, which may use the received signal Y 702 and the estimated channel impulse response Ĥ 706 to recover the data included in the received signal Y 702.

The received signal Y 702 may be expressed as:

$$Y = SH + W = [ \sqrt{\frac{{ρ}_{p}}{{m}_{T}}} {PX}^{( p )} + \sqrt{\frac{{ρ}_{d}}{{m}_{T}}} {QX}^{( d )} ] H + W \qquad \text{Equation} ( 4 )$$

where H is the channel coefficient matrix with size of m_{T}×m_{R}, and W is an m_{R} dimensional AWGN vector whose elements are independent and identically distributed (i.i.d.), and whose sample values may include ε [symbol] ^{m}R. In one embodiment, S represents the information signal. The channel estimation unit 704 may implement a linear estimator to estimate H in order to obtain the channel estimation Ĥ 706. In one embodiment, H is normalized such that ∥H∥²=1. The projection of the received signal Y 702 may be in the direction of PX^{(p)} so that the received signal Y 702 may be a sufficient statistic. In one embodiment, the received signal Y 702 is left multiplied by (PX^{(p)})⁺, where (PX)^{(p)})⁺ is the pseudo-inverse of PX^{(p)}. The product of this multiplication yields the following:

$$\begin{matrix}{( {PX}^{( p )} )}^{+} Y = \sqrt{\frac{{ρ}_{p}}{{m}_{T}}} {( {PX}^{( p )} )}^{+} {PX}^{( p )} H + \sqrt{\frac{{ρ}_{d}}{{m}_{T}}} {( {PX}^{( p )} )}^{+} {QX}^{( d )} H + {( {PX}^{( p )} )}^{+} W & Equation ( 5 ) \\ {( {PX}^{( p )} )}^{+} Y = \sqrt{\frac{{ρ}_{p}}{{m}_{T}}} H + {( {PX}^{( p )} )}^{+} W & Equation ( 6 )\end{matrix}$$

The cancellation of data (from equation (5) to equation (6)) is because the matrix Q is orthogonal to PX^{(p)}. In one embodiment, PX^{(p)} is known to both the transmitter and the receiver 700. As such, (PX^{(p)})⁺ may be pre-computed and stored at the receiver 700.

In a further embodiment, a zero-forcing estimator may be implemented by the channel estimation unit 704 to obtain the channel estimation Ĥ 706. For example, if the effect of noise is neglected, the channel estimation Ĥ 706 of H may be given by:

$$\hat{H} = \sqrt{\frac{{m}_{T}}{{ρ}_{P}}} {( {PX}^{( p )} )}^{+} Y \qquad Equation ( 7 )$$

If a minimum mean-square error (MMSE) linear estimator is implemented by the channel estimation unit 704, the channel estimation Ĥ 706 of H is given by:

$$\hat{H} = \sqrt{\frac{{m}_{T}}{{ρ}_{P}}} {( {PX}^{( p )} )}^{+} Y / ( I + {σ}_{1}^{2} ) , \qquad Equation ( 8 )$$

where σ₁² is the variance of (PX^{(p)})⁺W, which may be estimated by additional noise power estimation techniques.

The channel estimation Ĥ 706, obtained from either equation (7) or equation (8) may be used by the channel equalization unit 718 to compensate the effects of the channel H. In one embodiment, the channel equalization unit 718 includes a linear signal estimator 708, a pilot canceller 712 and a data recovery unit 716.

The channel equalization unit 718 may estimate S from equation (4) provided above. In one embodiment, the linear signal estimation 708 may estimate S using a linear estimation. As the linear signal estimation 708 estimates S, the channel estimation Ĥ 706 is used instead of H in equation (4) and S is treated as an unknown value that is to be estimated. In one embodiment, the projection of Y is in the direction of Ĥ, which may be a sufficient statistic. The received signal Y 702 may be right multiplied by Ĥ⁺ where Ĥ⁺ is the pseudo-inverse of Ĥ. The multiplication of YĤ⁺ may yield the following:

$$\begin{matrix}Y {\hat{H}}^{+} = \sqrt{\frac{{ρ}_{p}}{{m}_{T}}} {PX}^{( p )} H {\hat{H}}^{+} + \sqrt{\frac{{ρ}_{d}}{{m}_{T}}} {QX}^{( d )} H {\hat{H}}^{+} + W {\hat{H}}^{+} & Equation ( 9 ) \\ Y {\hat{H}}^{+} = \sqrt{\frac{{ρ}_{p}}{{m}_{T}}} {PX}^{( p )} + \sqrt{\frac{{ρ}_{d}}{{m}_{T}}} {QX}^{( d )} + W {\hat{H}}^{+} & Equation ( 10 ) \\ Y {\hat{H}}^{+} = S + W {\hat{H}}^{+} & Equation ( 11 )\end{matrix}$$

Several linear techniques may be implemented to obtain a signal estimate Ŝ 710, which is an estimate of S. In one embodiment, the linear signal estimator 708 may implement a zero-forcing estimator to obtain the signal estimate Ŝ 710. For example, the effect of noise may be neglected with a zero-forcing estimator and the signal estimate Ŝ 710 of S may be given by:

Ŝ=Y Ĥ⁺ Equation (12)

In another embodiment, the linear signal estimator 708 may implement a MMSE estimator to obtain the signal estimate Ŝ 710. If a MMSE estimator is used, the signal estimate Ŝ 710 may be given by:

Ŝ=Y Ĥ⁺∥S∥²/∥S∥²+σ₂²), Equation (13)

where ρ₂² is the variance of WĤ⁺ which may be estimated by a noise power estimation technique.

In one embodiment, the channel equalization unit 718 may cancel the pilot portion (also known as the reference portion) of the received signal Y 702. The pilot canceller 712 may cancel the pilot portion from received signal Y 702. In other words, the pilot portion (or pilot signal) is separated from the data in the received signal Y 702. From equation (3) provided above, S is a component of the pilot portion PX^{(p)} and data portion. As such, an estimation of the data portion (Q\hat{X}^{(d)}) 714 may be given by:

$$Q {\hat{X}}^{( d )} = \sqrt{\frac{{m}_{T}}{{ρ}_{d}}} ( \hat{S} - \sqrt{\frac{{ρ}_{p}}{{m}_{T}}} {PX}^{( p )} ) \qquad Equation ( 14 )$$

where Ŝ may be obtained from equation (12) or equation (13).

The estimation of the data portion (Q\hat{X}^{(d)}) 714 may be input to the data recover unit 716 so that the data may be recovered. The data may be estimated (i.e., recovered) from various observables with the pilot portion cancelled. The estimated data \hat{X}^{(d)} 720 may be expressed as:

\hat{X}^{(d)}=Q⁺Q\hat{X}^{(d)} Equation (15)

where Q⁺ is the pseudo-inverse of Q. In one embodiment, Q is known to both the transmitter and the receiver. As such, Q⁺ may be pre-computed and stored at the receiver.

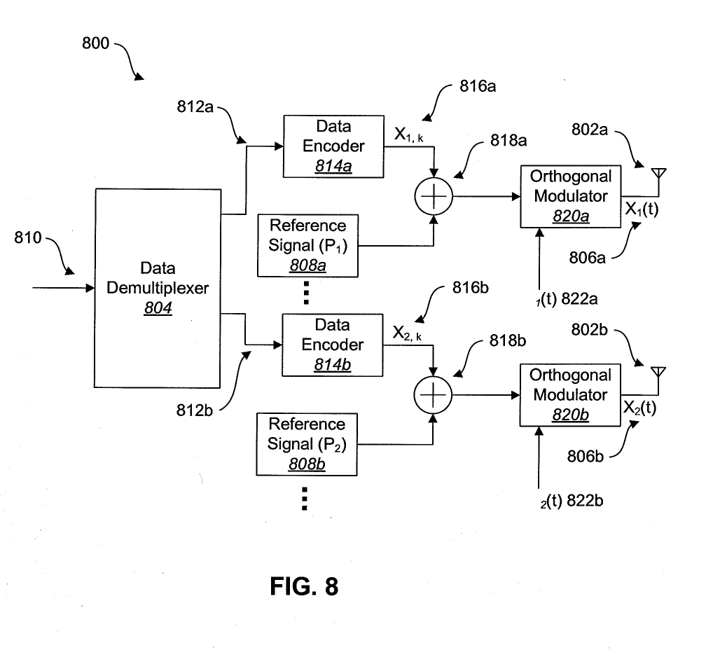

FIG. 8 is a block diagram illustrating one embodiment of a transmitter 800 in which two antennas 802a and 802b are used to transmit two data signals x₁(t) 806a and x₂(t) 806b simultaneously with two reference signals P₁ 808a and P₂ 808b using an orthogonal modulation. Some embodiments of the transmitter 800 may include a single antenna. In other embodiments, the transmitter 800 may include multiple antennas.

The transmitter 800 may include a data demultiplexer 804, which serves to receive a single data signal 810 and then split the single data signal 810 into multiple signals 812a and 812b. The multiple signals 812a, 812b may be encoded by a data encoder 814a, 814b which serves to change a signal or data into code. The output of each data encoder 814a, 814b may be referred to as x_{1,k} 816a and x_{2,k} 816b. A summation function 818a, 818b may sum the output of the data encoders 814a, 814b with the reference signals 808a, 808b. An orthogonal modulator 820a, 820b may modulate the summed signals with orthogonal functions φ₁(t) 822a and φ₂(t) 822b. The transmitter antennas 802a, 802b may transmit the modulated signals to a receiver. An explanation of a superposition of reference signals onto data for multiple antenna transmission from the transmitter 800 is now provided.

In transmitting a signal in a band of interval

$$[ \frac{- W}{2} , \frac{W}{2} )$$

in duration of T, WT orthogonal waveforms may be transmitted. With m_{T} transmit antennas, there is a coherence time of T symbols available, to be allocated amongst pilot and data symbols. If an orthogonal waveform may be transmitted in one of these symbols times (denoted as Tₛ, such that T=K Tₛ, in bandwidth W), then there may be (with m_{T}=m_{R}=m antennas) up to mWK orthogonal waveforms that may be transmitted in time T, if the multiple antenna channels truly behave as independent channels.

In one embodiment, the summation function 818 may yield (P₁+x_{1,k}), which may be modulated by the orthogonal modulator 820a. (P₁+x_{1,k}) may be modulated by the orthogonal function φ₁(t) 822a, in time [(k−1)Tₛ, kTₛ). In other words x₁(t)=(P₁+x_{1,k}) φ₁(t), and

$${\int }_{( k - 1 ) {T}_{s}}^{{kT}_{S}} {φ}_{1} ( t ) {φ}_{2}^{*} ( t ) d t = 0$$

so that at a receiver, a correlation may be performed with the appropriate orthogonal function φ₁(t) 822a which may yield an estimate of (P₁+x_{1,k}). The estimate of (P₁+x_{1,k}) may include additive noise.

An added requirement that

$${\int }_{T} {\sum }_{κ} {x}_{ικ} P ( t - κ {T}_{s} ) d τ = 0$$

may indicate that the number of orthogonal signals transmitted over any given antenna may be two. Further, the number of reference signals transmitted may also be two. The above mentioned example provides the same occupancy of degrees of freedom as with the Hassibi and Hochwald states. In one embodiment, these degrees of freedom may come from the orthogonal modulation. In particular, if an OFDM modulation is implemented, then the reference signal P₁ 808a occupies the 0 Hz carrier position of the modulation.

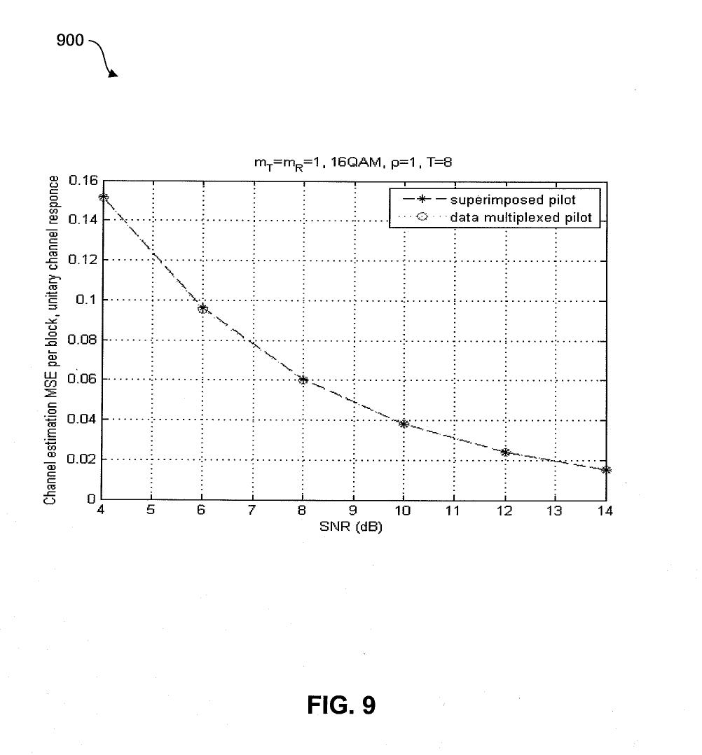

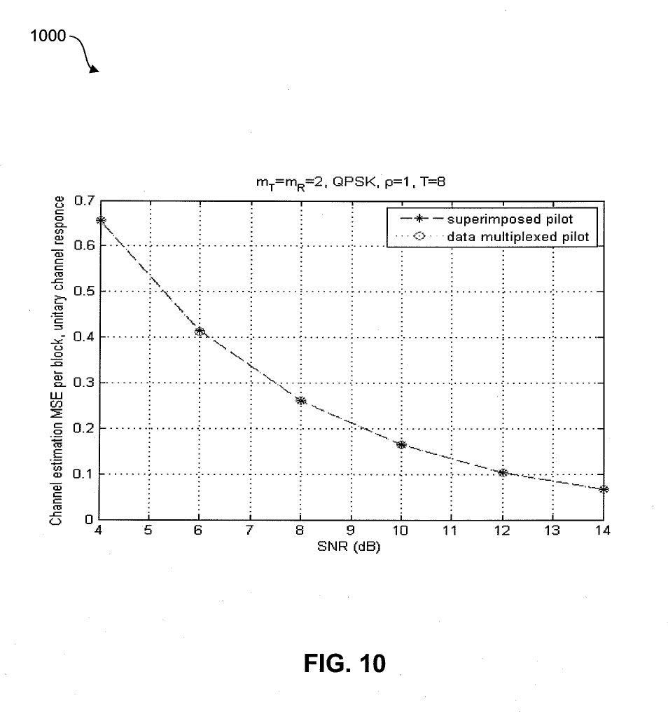

FIGS. 9 and 10 are charts illustrating one embodiment of results 900, 1000 regarding the mean square error (MSE) of channel estimation (H-Ĥ)². FIG. 9 is an example of the performance of channel estimation of a superimposed pilot signal vs. a TDM pilot signal for a single (1 by 1) antenna system. FIG. 10 is an example of the performance of channel estimation of a superimposed pilot signal vs. a TDM pilot signal for a multiple antenna (2 by 2) system.

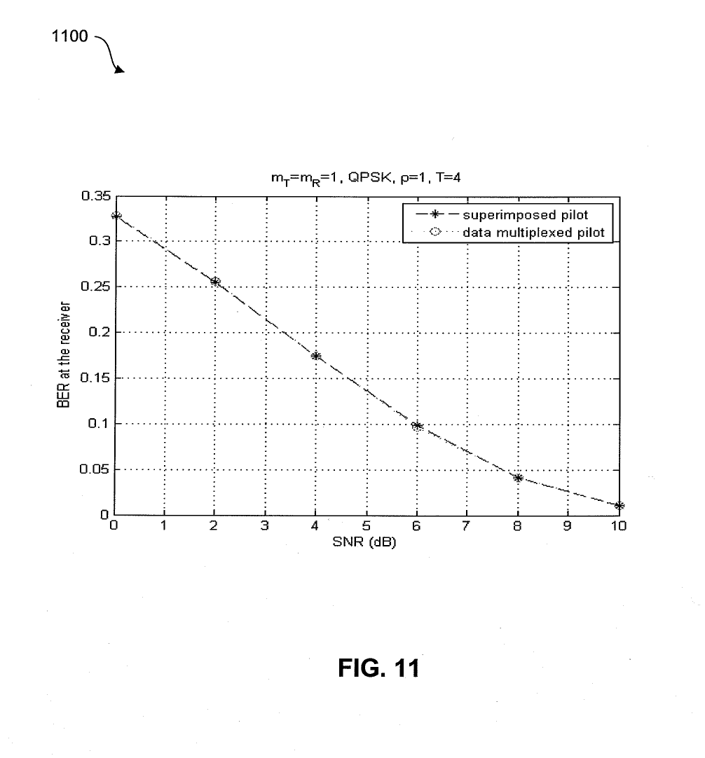

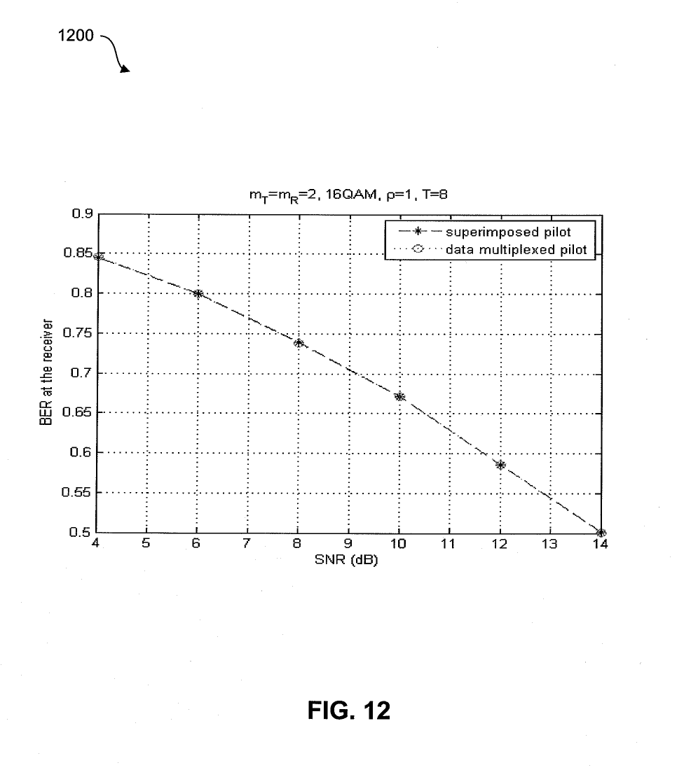

FIG. 11 is a chart illustrating one embodiment of the results 1100 regarding the Bit Error Ratio (BER) performance of a superimposed pilot signal vs. a TDM pilot signal for a single (1 by 1) antenna system. FIG. 12 is a example of the results 1200 regarding the BER performance of a superimposed pilot signal vs. a TDM pilot signal for a multiple antenna (2 by 2) system.

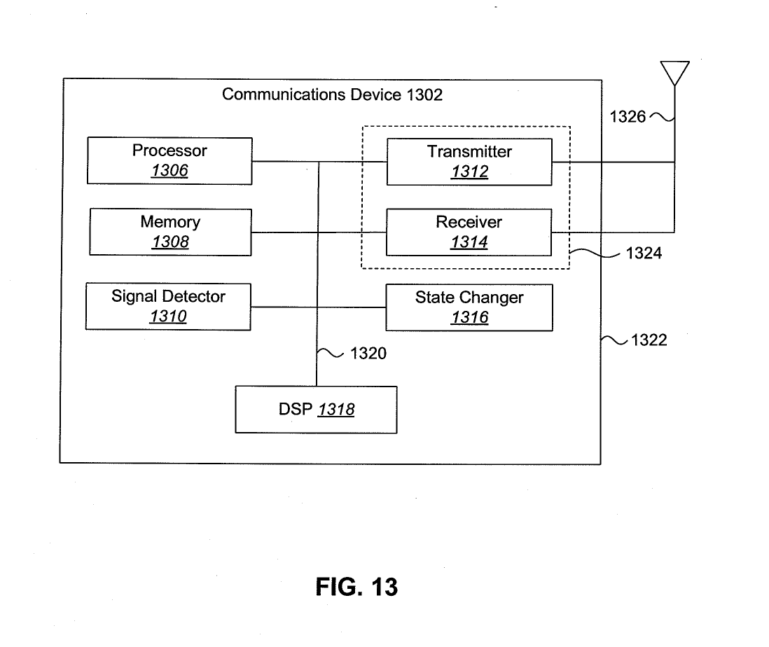

FIG. 13 illustrates various components that may be utilized in a communications device 1302. The communications device 1302 may include any type of communications device such as a mobile station, a cell phone, an access terminal, user equipment, a base station transceiver, a base station controller, etc. The communications device 1302 includes a processor 1306 which controls operation of the communications device 1302. The processor 1306 may also be referred to as a CPU. Memory 1308, which may include both read-only memory (ROM) and random access memory (RAM), provides instructions and data to the processor 1306. A portion of the memory 1308 may also include non-volatile random access memory (NVRAM).

The communications device 1302 may also include a housing 1322 that contains a transmitter 1312 and a receiver 1314 to allow transmission and reception of data. The transmitter 1312 and receiver 1314 may be combined into a transceiver 1324. An antenna 1326 is attached to the housing 1322 and electrically coupled to the transceiver 1324. Additional antennas (not shown) may also be used.

The communications device 1302 may also include a signal detector 1310 used to detect and quantify the level of signals received by the transceiver 1324. The signal detector 1310 detects such signals as total energy, pilot energy, power spectral density, and other signals.

A state changer 1316 controls the state of the communications device 1302 based on a current state and additional signals received by the transceiver 1324 and detected by the signal detector 1310. The communications device 1302 may be capable of operating in any one of a number of states.

The various components of the communications device 1302 are coupled together by a bus system 1320 which may include a power bus, a control signal bus, and a status signal bus in addition to a data bus. However, for the sake of clarity, the various buses are illustrated in FIG. 13 as the bus system 1320. The communications device 1302 may also include a digital signal processor (DSP) 1318 for use in processing signals. The communications device 1302 illustrated in FIG. 13 is a functional block diagram rather than a listing of specific components.

Information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention.

The various illustrative logical blocks, modules, and circuits described in connection with the embodiments disclosed herein may be implemented or performed with a general purpose processor, a digital signal processor (DSP), an application specific integrated circuit (ASIC), a field programmable gate array signal (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The steps of a method or algorithm described in connection with the embodiments disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

The methods disclosed herein comprise one or more steps or actions for achieving the described method. The method steps and/or actions may be interchanged with one another without departing from the scope of the present invention. In other words, unless a specific order of steps or actions is required for proper operation of the embodiment, the order and/or use of specific steps and/or actions may be modified without departing from the scope of the present invention.

While specific embodiments and applications of the present invention have been illustrated and described, it is to be understood that the invention is not limited to the precise configuration and components disclosed herein. Various modifications, changes, and variations which will be apparent to those skilled in the art may be made in the arrangement, operation, and details of the methods and systems of the present invention disclosed herein without departing from the spirit and scope of the invention.

What is claimed is:

1. A method for processing a signal within a communications system, the method: comprising:
receiving a signal transmitted over a channel that includes an information signal and a reference signal, wherein the information signal comprises data, and wherein the reference signal is superimposed on the data;
estimating a channel impulse response of the channel based on the reference signal; and
equalizing the information signal based on the estimation of the channel impulse response by compensating the signal, estimating the information signal, canceling the reference signal and recovering the data.

2. The method of claim 1, wherein the signal is received by a communications device comprising a single antenna.

3. The method of claim 1, wherein one or more signals is received by a communications device comprising multiple antennas.

4. The method of claim 1, further comprising multiplying a vector of the signal by a conjugate transposed vector of a symbol of the reference signal for a single antenna communications device.

5. The method of claim 1, further comprising multiplying a matrix of the signal by a conjugate transposed matrix of symbols of one or more reference signals for a multiple antenna communications device.

6. The method of claim 1, wherein equalizing the information signal for a single antenna communications device further comprises:
multiplying a vector of the information signal by the inverse of a channel estimation and estimating the information signal;
canceling the reference signal; and
multiplying the information signal by the pseudo-inverse of a linear transformation matrix used at a transmitter to recover the data.

7. The method of claim 1, wherein equalizing the information signal for a multiple antenna communications device further comprises:
multiplying a matrix of the information signal by the inverse of a channel estimation matrix and estimating the information signal;
canceling the reference signal; and
multiplying the information signal by the pseudo-inverse of a linear transformation matrix used at a transmitter to recover the data.

8. The method of claim 1, further comprising a class of linear receivers.

9. The method of claim 1, wherein the channel impulse response is estimated using zero-forcing estimation.

10. The method of claim 1, wherein the channel impulse response is estimated using minimum mean square error (MMSE) estimation.

11. The method of claim 1, wherein the information signal is estimated using zero-forcing estimation.

12. The method of claim 1, wherein the information signal is estimated using minimum mean square error (MMSE) estimation.

13. A communications device that is configured to process a signal within a communications system, the communication device comprising:
a processor;
memory in electronic communication with the processor;
instructions stored in the memory, the instructions being executable to:
receive a signal transmitted over a channel that includes an information signal and a reference signal, wherein the information signal comprises data, and wherein the reference signal is superimposed on the data;
estimate a channel impulse response of the channel based on the reference signal; and
equalize the information signal based on the estimation of the channel impulse response by compensating the signal, estimating the information signal, canceling the reference signal and recovering the data.

14. The communications device of claim 13, wherein the communications device comprises a single antenna.

15. The communications device of claim 13, wherein the communications device comprises multiple antennas.

16. The communications device of claim 13, wherein the instructions are further executable to multiply a vector of the signal by a conjugate transposed vector of a symbol of the reference signal for a single antenna communications device.

17. The communications device of claim 13, wherein the instructions are further executable to multiply a matrix of the signal by a conjugate transposed matrix of symbols of one or more reference signals for a multiple antenna communications device.

18. The communications device of claim 13, wherein the instructions to equalize the information signal for a single antenna communications device are further executable to:
multiply a vector of the information signal by the inverse of a channel estimation and estimating the information signal;
cancel the reference signal; and
multiply the information signal by the pseudo-inverse of a linear transformation matrix used at a transmitter to recover the data.

19. The communications device of claim 13, wherein the instructions to equalize the information signal for a multiple antenna communications device are further executable to:
multiply a matrix of the information signal by the inverse of a channel estimation matrix and estimating the information signal;
cancel the reference signal; and
multiply the information signal by the pseudo-inverse of a linear transformation matrix used at a transmitter to recover the data.

20. A computer-readable medium comprising executable instructions for:
receiving a signal transmitted over a channel that includes an information signal and a reference signal, wherein the information signal comprises data, and wherein the reference signal is superimposed on the data;
estimating a channel impulse response of the channel based on the reference signal; and
equalizing the information signal based on the estimation of the channel impulse response by compensating the signal, estimating the information signal, canceling the reference signal and recovering the data.
